(19) United States
(12) Patent Application Publication
(10) Pub. No.: US 2021/0071302 A1
(43) Pub. Date: Mar. 11, 2021

(54) SUBSTRATE PROCESSING APPARATUS AND SUBSTRATE PROCESSING METHOD

(71) Applicant: TOKYO ELECTRON LIMITED, Tokyo (JP)

(72) Inventor: Sumi TANAKA, Nirasaki City (JP)

(21) Appl. No.: 17/005,818

(22) Filed: Aug. 28, 2020

(30) Foreign Application Priority Data
Sep. 6, 2019 (JP) 2019-162893

(51) Int. Cl. C23C 16/48; C23C 16/458; C23C 16/455; C23C 16/24

(52) U.S. Cl. CPC C23C 16/48; C23C 16/24; C23C 16/45565; C23C 16/4584

(57) ABSTRACT

A substrate processing apparatus for processing a substrate is provided. In the substrate processing apparatus, a substrate support has an upper surface on which a substrate is placed and serves to heat the substrate placed thereon. At least one substrate support pin is configured to protrude from and retract below the upper surface of the substrate support and to support the substrate. Further, a light irradiation mechanism is configured to irradiate light to a specific portion of the substrate placed on the upper surface of the substrate support, corresponding to a position where the at least one substrate support pin protrudes and retracts, to heat the specific portion.

### CROSS-REFERENCE TO RELATED APPLICATION

This application claims priority to Japanese Patent Application No. 2019-162893, filed on Sep. 6, 2019, the entire contents of which are incorporated herein by reference.

### TECHNICAL FIELD

The present disclosure relates to a substrate processing apparatus and a substrate processing method.

### BACKGROUND

Japanese Patent Application Publication No. H11-111821 discloses a substrate processing apparatus that prevents uniformity of substrate processing from being adversely affected by flow-around of a processing gas in the case of processing a substrate at a high temperature. This substrate processing apparatus includes a susceptor, an elevating driving unit, a plurality of substrate support pins, and a movement blocking member. The susceptor is disposed horizontally, and a substrate is supported on an upper surface of the susceptor. The susceptor is moved vertically by the elevating driving unit between a first position where the substrate is supported and a second position where the substrate is on standby, the second position being lower than the first position. The substrate support pins are supported to be movable in a vertical direction with respect to the susceptor. When the susceptor is located at the second position, the substrate W is supported by the substrate support pins. When the susceptor is moved from the first position to the second position, the substrate support pins are prevented from moving downward by the movement blocking member. The susceptor has pin insertion holes into which the substrate support pins are inserted.

The technique of the present disclosure improves the in-plane uniformity of the temperature of the substrate in the case of heating the substrate by the substrate support, the substrate being placed on the upper surface of the substrate support where the substrate support pins protrude from and retract below.

### SUMMARY

In accordance with an aspect of the present disclosure, there is provided a substrate processing apparatus for processing a substrate, including: a substrate support having an upper surface on which a substrate is placed and serving to heat the substrate placed thereon; at least one substrate support pin configured to protrude from and retract below the upper surface of the substrate support and to support the substrate; and a light irradiation mechanism configured to irradiate light to a specific portion of the substrate placed on the upper surface of the substrate support, corresponding to a position where the at least one substrate support pin protrudes and retracts, to heat the specific portion.

### BRIEF DESCRIPTION OF THE DRAWINGS

The objects and features of the present disclosure will become apparent from the following description of embodiments, given in conjunction with the accompanying drawings, in which:

FIG. 1 is an explanatory diagram schematically showing a configuration of a film forming apparatus as a substrate processing apparatus according to a first embodiment;

FIG. 2 is a top view of a substrate support and shows a positional relationship among openings of the substrate support, support pins, and light introducing paths in the first embodiment;

FIG. 3 is an explanatory diagram schematically showing a configuration of a film forming apparatus as a substrate processing apparatus according to a second embodiment;

FIG. 4 is a top view of the substrate support and shows a positional relationship among openings of the substrate support, support pins, and light introducing paths in the second embodiment; and

FIG. 5 shows another example of a formation position of the light introducing path.

### DETAILED DESCRIPTION

For example, in a semiconductor device manufacturing process, substrate processing such as film formation processing or the like is performed on a substrate such as a semiconductor wafer (hereinafter referred to as “wafer”) or the like. The substrate processing is performed by a substrate processing apparatus. When the substrate processing apparatus is a single-wafer processing apparatus that processes substrates one by one, a substrate support having an upper surface on which a substrate is placed is disposed in the apparatus. Further, the single-wafer processing apparatus has substrate support pins as disclosed in Japanese Patent Application Publication No. H11-111821 to transfer the substrate between the substrate support and a substrate transfer unit for transferring the substrate. The substrate support pins are configured to protrude from or retract below the upper surface of the substrate support while vertically moving with respect to the substrate support. Further, the substrate support has openings through which upper ends of the substrate support pins penetrate when the substrate support pins are moved vertically to protrude from and retract below the upper surface of the substrate support.

During the substrate processing, the substrate placed on the substrate support may be heated via the substrate support. In that case, if the substrate support pins are provided, a temperature may be relatively decreased at specific portions of the substrate placed on the substrate support corresponding to the positions where the substrate support pins protrude and retract, such as the portions corresponding to the openings of the substrate support and the like. Accordingly, the in-plane uniformity of the temperature of the substrate may deteriorate.

Therefore, the technique of the present disclosure improves the in-plane uniformity of the temperature of the substrate in the case of heating the substrate by the substrate support, the substrate being placed on the upper surface of the substrate support where the substrate support pins protrude and retract.

Hereinafter, a substrate processing apparatus and a substrate processing method according to the present embodiment will be described with reference to the accompanying drawings. In this specification and the drawings, like reference numerals will be given to like parts having substantially the same functions, and redundant description thereof will be omitted.

### First Embodiment

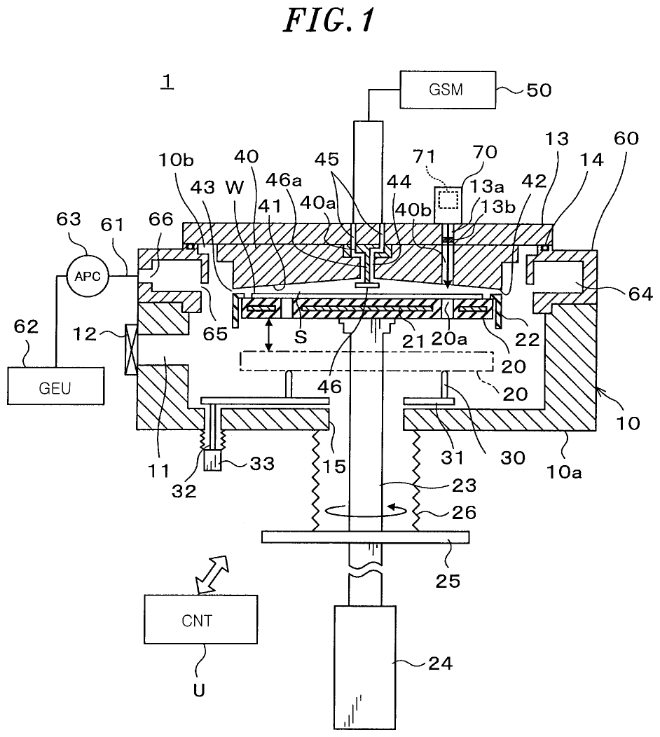

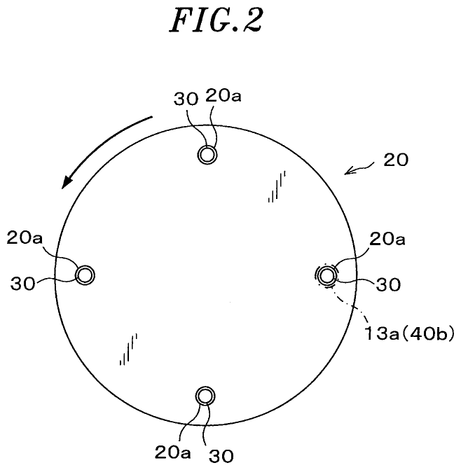

FIG. 1 is an explanatory diagram schematically showing a configuration of a film forming apparatus as a substrate processing apparatus according to a first embodiment. FIG. 1 shows a cross section of a part of the film forming apparatus. FIG. 2 is a top view of a substrate support 20 and shows a positional relationship among openings 20a of the substrate support 20, support pins 30, and light introducing paths 13a and 40b, which will be described later.

The film forming apparatus 1 of FIG. 1 includes a depressurizable processing chamber 10 accommodating a wafer W as a substrate.

The processing chamber 10 has a cylindrical chamber main body 10a having a closed bottom.

A wafer loading/unloading port 11 is disposed on a sidewall of the chamber main 10a, and is provided with a gate valve 12 for opening/closing the loading/unloading port 11. A gas exhaust duct 60 to be described later is disposed above the loading/unloading 11 and forms a part of the sidewall of the chamber main body 10a. An opening 10b is formed at an upper portion of the chamber main body 10a, i.e., at the gas exhaust duct 60, and a lid 13 is attached to block the opening 10b. An O-ring 14 for maintaining the inside of the processing chamber 10 in an airtight state is disposed between the gas exhaust duct 60 and the lid 13.

The substrate support 20 having an upper surface on which a wafer W is horizontally placed is disposed in the processing chamber 10. A heater 21 for heating the wafer W is disposed inside the substrate support 20.

The substrate support 20 is provided with a cover member 22 that covers an outer peripheral region of a substrate supporting region of the wafer W on the upper surface of the substrate support 20 and a side peripheral surface thereof in a circumferential direction.

An upper end of a support shaft member 23 extending in a vertical direction while penetrating through a bottom wall of the processing chamber 10 through an opening 15 formed in the bottom wall is connected to a central portion of a bottom surface of the substrate support 20. A lower end of the support shaft member 23 is connected to a driving mechanism 24 as a rotation driving mechanism. The driving mechanism 24 generates a driving force for vertically moving and rotating the support shaft member 23. The driving mechanism 24 has, e.g., an air cylinder (not shown) or a motor (not shown). As the support shaft member 23 is moved vertically by the driving of the driving mechanism 24, the substrate support 20 can be moved vertically between a transfer position indicated by a dashed double-dotted line and a processing position higher than the transfer position. The transfer position is a position where the substrate support 20 is on standby when a wafer W is transferred between a wafer transfer mechanism (not shown) that enters the processing chamber 10 through the loading/unloading port 11 of the processing chamber 10 and the support pins 30 to be described later. The processing position is a position where film formation is performed on the wafer W. Further, as the support shaft member 23 rotates about its axis by the driving of the driving mechanism 24, the substrate support 20 rotates about the axis.

A flange 25 is disposed at the support shaft member 23 outside the processing chamber 10. A bellows 26 is disposed between the flange 25 and a portion of the bottom wall of the processing chamber 10 where the support shaft member 23 penetrates to surround an outer peripheral portion of the support shaft member 23. Accordingly, the processing chamber 10 can be maintained in an airtight state.

Further, the support pins 30 as substrate support pins are vertically movable with respect to the substrate support 20. The support pins 30 are used to transfer the wafer W between a transfer unit (not shown) of the wafer W that enters the processing chamber 10 from the outside of the processing chamber 10 and the substrate support 20. The upper ends of the support pins 30 can protrude from and retract below the upper surface of the substrate support 20 while the support pins 30 are vertically moving. Further, the support pins 30 are configured to support the wafer W while protruding from the upper surface of the substrate support 20. The openings 20a through which the upper ends of the support pins 30 penetrate when the support pins 30 are vertically moved to protrude from and retract below the upper surface of the substrate support 20 are formed in the upper surface of the substrate support 20. In this example, the openings 20a are through-holes extending in the vertical direction. The support pins 30 are inserted into the openings 20a from below and penetrate therethrough. As shown in FIG. 2, there are a plurality of (four in this example) support pins 30 and a plurality of (four in this example) openings 20a, and multiple sets of the support pins 30 and the openings 20a through which the support pins 30 corresponding thereto penetrate are arranged at equal intervals along a circumferential direction of the substrate support 20 in plan view. When a wafer W has a diameter of, e.g., 300 mm, the support pin 30 and the opening 20a have diameters of 9 mm and 10 mm, respectively, in plan view.

As shown in FIG. 1, the lower ends of the support pins 30 are connected to an upper surface of a wafer elevating member 31 disposed below the substrate support 20 in the processing chamber 10. A support column 32 is disposed on a bottom surface of the wafer elevating member 31 and penetrates through the bottom wall of the processing chamber 10 to be connected to an elevating mechanism 33 disposed outside the processing chamber 10. Therefore, the wafer elevating member 31 can be moved vertically by the driving of the elevating mechanism 33. As the wafer elevating member 31 is vertically moved, the support pins 30 protrude from and retract below the upper surface of the substrate support 20 through the openings 20a of the substrate support 20.

Further, a cap member 40 for forming a processing space S between the substrate support 20 and the lid 13 in the processing chamber 10 is disposed to face the substrate support 20. The cap member 40 is fixed to the lid 13 with bolts (not shown).

An inverted bowl-shaped recess 41 is formed at a bottom portion of the cap member 40, and a flat rim 42 is formed at an outer side of the recess 41.

The processing space S is formed by the upper surface of the substrate support 20 located at the processing position and the recess 41 of the cap member 40. The height of the substrate support 20 at the time when the processing space S is formed is set such that a gap 43 is formed between the bottom surface of the rim 42 of the cap member 40 and the upper surface of the cover member 22. The recess 41 is formed such that the volume of the processing space S is minimized and a processing gas can be effectively replaced with a purge gas.

A gas inlet line 44 for introducing a processing gas or a purge gas into the processing space S is formed at the central portion of the cap member 40. The gas inlet line 44 penetrates through the central portion of the cap member 40, and a lower end of the gas inlet line 44 is disposed to face the central portion of the wafer W on the substrate support 20. A flow path forming member 40a is fitted in the central portion of the cap member 40. Due to the presence of the flow path forming member 40a, an upper side of the gas inlet line 44 is branched into multiple parts communicating with gas inlet lines 45 penetrating through the lid 13. A gas supply mechanism (GSM) 50 for supplying SiH₄ gas as a processing gas, N₂ gas as a purge gas, or the like is connected to the gas inlet line 45.

A dispersion plate 46 for dispersing a gas injected from the gas inlet line 44 into the processing space S is disposed below the lower end of the gas inlet line 44 of the cap member 40. The dispersion plate 46 is fixed to the cap member 40 via a support rod 46a.

Further, one end of a gas exhaust line 61 is connected to the gas exhaust duct 60 forming a part of the sidewall of the chamber main body 10a. The other end of the gas exhaust line 61 is connected to a gas exhaust unit (GEU) 62 including, e.g., a vacuum pump. In addition, an APC valve 63 for adjusting a pressure in the processing space S is disposed at an upstream side of the gas exhaust line 61 compared to the gas exhaust unit 62.

The gas exhaust duct 60 has an annular gas flow passage 64 having a rectangular vertical cross section. Slits 65 are formed over the entire inner peripheral surface of the exhaust duct 60. A gas exhaust port 66 is disposed on an outer wall of the gas exhaust duct 60, and the gas exhaust line 61 is connected to the gas exhaust port 66. The slits 65 are formed at positions corresponding to the gap 43 formed when the substrate support 20 is raised to the processing position. Therefore, when the gas exhaust device 62 is driven, the gas in the processing space S reaches the gas flow passage 64 of the gas exhaust duct 60 through the gap 43 and the slits 65, and then is exhausted through the gas exhaust line 61.

The film forming apparatus 1 further includes a light irradiation mechanism 70. The light irradiation mechanism 70 irradiates light to specific portions of the wafer W placed on the upper surface of the substrate support 20 corresponding to the positions where the support pins 30 protrude and retract, so that the specific portions are heated. Specifically, the light irradiation mechanism 70 irradiates laser light from above, the laser light having directivity to portions (hereinafter, pin position portions) of the wafer W placed on the upper surface of the substrate support 20 that are directly above the openings 20a through which the support pins 30 penetrate and performs pinpoint heating on the pin position portions. The light irradiation mechanism 70 heats the pin position portions of the wafer W as described above to correct the temperatures of the pin position portions to those of the other portions of the wafer W.

The light irradiation mechanism 70 has a laser light source 71 that emits laser light.

An irradiation intensity of the laser light from the laser light source 71 may be fixed or variable. In the present embodiment, the irradiation intensity of the laser light is fixed at 1400 W.

A wavelength of the light emitted from the laser light source 71 is selected depending on a material of the wafer W. For example, when the wafer W is made of silicon, a wavelength of the light emitted from the laser light source 71 is set to 0.36 μm to 1.0 μm so that a high absorption efficiency (higher than or equal to 60%) to silicon can be ensured regardless of a temperature.

In the present embodiment, the light irradiation mechanism 70 is disposed outside the processing chamber 10. Specifically, the laser light source 71 of the light irradiation mechanism 70 is disposed outside the processing chamber 10.

Then, light introducing paths 13a and 40b are formed through the lid 13 and the cap member 40 so that the light from the laser light source 71 disposed outside the processing chamber 10 can be irradiated to the wafer W placed on the substrate support 20 in the processing chamber 10. The light introducing paths 13a and 40b for introducing the laser light from the laser light source 71 disposed outside the processing chamber 10 into the processing chamber 10 are formed as through-holes extending vertically and communicating with each other.

The following is description on formation positions of the light introducing paths 13a and 40b with respect to the substrate support 20. In other words, as shown in FIG. 2, the light introducing paths 13a and 40b are formed above the substrate support 20 to overlap with the wafer W placed on the substrate support 20 in plan view. Specifically, the light introducing paths 13a and 40b are formed directly above a trajectory in which the openings 20a move by the rotation of the substrate support 20 about the axis of the support shaft member 23 as described above.

Further, as shown in FIG. 1, the light introducing path 13a is provided with a window 13b for maintaining the processing chamber 10 in an airtight state. The window 13b is made of a material that transmits the laser light from the laser light source 71. Specifically, the window 13b is made of, e.g., quartz or sapphire that efficiently transmits laser light having a wavelength of 0.36 μm to 1.0 μm. Since the window 13b is made of quartz or sapphire, it is possible to prevent the window 13b from being damaged when a corrosive gas is introduced into the processing chamber 10 during film formation.

The light emitted from the laser light source 71 of the light irradiation mechanism 70 is irradiated to the wafer W placed on the substrate support 20 through the window 13b.

In this example, the window 13b is disposed at the light introducing path 13a. However, a window similar to the window 13b may be disposed at the light introducing path 40b instead of the window 13b or in addition to the window 13b.

In the illustrated example, one set of the light irradiation mechanism 70 and the light introducing paths 13a and 40b is provided. However, multiple sets of the light irradiation mechanisms 70 and the light introducing paths 13a and 40b may be provided. The number of the light irradiation mechanisms 70 is determined based on an intensity of the laser light emitted from the light irradiation mechanism 70 and a target correction amount of the temperatures of the pin position portions of the wafer W to be corrected by the light irradiation mechanisms 70.

The emission timing of the laser light from the light irradiation mechanism 70 is controlled by a controller (CNT) U described later in accordance with the rotation of the substrate support 20. Accordingly, the laser light is irradiated only to the pin position portions of the wafer W on the substrate support 20. In other words, the light irradiation mechanism 70 is controlled by the controller U to be described later to irradiate laser light only when the pin position portions of the wafer W placed on the rotating substrate support 20 pass through region (hereinafter, referred to as “irradiation region”) of the wafer W to which the laser light from the light irradiation mechanism 70 can be irradiated. In this example, the light irradiation mechanism 70 irradiates laser light, under the control of the controller U to be described later, only when the pin position portions of the wafer W placed on the rotating substrate support 20, i.e., the openings 20a of the substrate support 20, pass through the region immediately below the light introducing path 40b of the cap member 40.

The size of the irradiation region of the laser light on the wafer W in plan view is 0.5 to 2.0 times greater than the size of each opening 20a of the substrate support 20. Specifically, when the irradiation region of the laser light and the openings 20a have a circular shape in plan view, for example, the diameter of the irradiation region of the laser light in plan view is 0.5 to 2 times greater than the diameter of each opening 20a. Further, when the irradiation region of the laser light has a rectangular shape and the openings 20a have a circular shape in plan view, for example, short sides and long sides of the irradiation region of the laser light in the plan view are 0.5 to 2.0 times greater than the diameter of each opening 20a. In this case, the area of the irradiation region of the laser light in plan view may be 0.25 to 4.0 times greater than that of each opening 20a.

The light irradiation mechanism 70 may have an optical system such as lens or the like to adjust the size of the irradiation region of the laser light. The optical system may be disposed at an outer side or an inner side of the window 13b.

The film forming apparatus 1 configured as described above includes the controller U for controlling the light irradiation mechanism 70, the driving mechanism 24, and the like. The controller U is, e.g., a computer including a CPU and a memory, and has a program storage unit (not shown). The program storage unit stores a program or the like for realizing wafer processing to be described later in the film forming apparatus 1. The program may be recorded in a computer-readable storage medium, and may be installed in the controller U from the storage medium. Further, a part or all of the programs may be realized by a dedicated hardware (circuit board).

Next, an example of wafer processing performed by the film forming apparatus 1 will be described.

First, the gate valve 12 is opened, and the wafer transfer mechanism holding the wafer W in a predetermined direction is loaded into the processing chamber 10 from a transfer chamber (not shown) of a vacuum atmosphere adjacent to the processing chamber 10 through the loading/unloading port 11. Then, the wafer W is transferred to a position above the substrate support 20 that has been moved to the above-described standby position. Then, the support pins 30 are lifted by driving the elevating mechanism 33. Accordingly, the support pins 30 protrude from the upper surface of the substrate support 20 by a predetermined distance, and the wafer W is transferred onto the support pins 30.

Then, the wafer transfer mechanism retreats from the processing chamber 10, and the gate valve 12 is closed. At the same time, the support pins 30 and the substrate support 20 are relatively moved, and the wafer W is placed on the upper surface of the substrate support 20. Specifically, the support pins 30 are lowered by the elevating mechanism 33 and the substrate support 20 is raised by the driving mechanism 24. Accordingly, the support pins 30 are retracted below the upper surface of the substrate support 20, and the wafer W is transferred from the support pins 30 onto the substrate support 20.

Next, a pressure in the processing chamber 10 is adjusted to a predetermined pressure, and the substrate support 20 is moved to the processing position by the driving mechanism 24. Accordingly, the processing space S is formed and, at the same time, the temperature of the wafer W is increased.

In the case of rotating the wafer W together with the substrate support 20 at the time of increasing the temperature of the wafer W, the temperature of the wafer W may be increased by the pre-heated substrate support 20 and the light irradiation mechanism 70. The heating using the light irradiation mechanism 70 at this time may be the same as or different from the heating using the light irradiation mechanism 70 in a subsequent film formation step. When the heating using the light irradiation mechanism 70 at this time is different from the heating using the light irradiation mechanism 70 in the subsequent film formation step, a temperature increasing speed of the former heating may be increased by increasing an output of the laser light such that a heat input in the former heating becomes greater than that in the latter heating.

When the temperature of the wafer W is increased without rotating the wafer W, the temperature of the wafer W is increased only by, for example, the pre-heated substrate support 20.

When the wafer W is heated to a desired temperature, film formation processing as predetermined processing is performed on the wafer W. Specifically, when the wafer W is heated to a desired temperature (e.g., 300° C. to 600° C.), SiH₄ gas is supplied to the processing space S by the gas supply mechanism 50, and amorphous silicon (a-Si) film is formed on the wafer W.

During this film formation, the wafer W is rotated together with the substrate support 20. The rotation speed of the wafer W is, e.g., 1 rpm to 60 rpm. Further, during the film formation, the rotating wafer W is entirely heated by the substrate support 20 adjusted to a desired temperature. When the heating is performed only by the substrate support 20, the temperatures of the pin position portions of the wafer W become lower than those of other portions and, thus, the in-plane uniformity of the temperature of the wafer W deteriorates. Therefore, the heating of the pin position portions by the light irradiation mechanism 70, i.e., the correction of the temperatures of the pin position portions by the light irradiation mechanism 70, is also performed. The light irradiation mechanism 70 corrects the temperatures of the pin position portions by, e.g., 3° C. to 4° C. The temperature correction amount may be, e.g., 3° C. to 10° C., by adjusting the number of light irradiation mechanisms 70, the rotation speed of the wafer, and the like.

In the case of heating the pin position portions by the light irradiation mechanism 70, the controller U controls the driving mechanism 24 and the light irradiation mechanism 70 such that the laser light is emitted from the light irradiation mechanism 70 in accordance with the rotation of the substrate support 20 and irradiated only to the pin position portions of the wafer W.

Specifically, the substrate support 20 is rotated together with the wafer W by driving the driving mechanism 24 under the control of the controller U. A rotational position of the substrate support 20, i.e., a rotational position of the wafer W, is detected based on information from an encoder or the like provided for a motor (not shown) of the driving mechanism 24. The light irradiation mechanism 70 is controlled based on the detection result such that the laser light source 71 emits laser light only when the pin position portions of the wafer W placed on the rotating substrate support 20 overlap with the irradiation region of the laser light. Accordingly, the laser light is emitted only to the pin position portions. The period of time of irradiating the laser light from the laser light source 71 to the pin position portions per once is predetermined depending on the irradiation intensity of the laser light emitted from the laser light source 71 or the rotation speed of the wafer W.

After the a-Si film is formed, the wafer W is unloaded from the processing chamber 10 in the reverse order of the above-described operation.

As described above, in the present embodiment, the film forming apparatus 1 includes the substrate support 20 having an upper surface on which the wafer W is placed and serving to heat the wafer W placed thereon, and the support pins 30 configured to protrude from and retract below the upper surface of the substrate support 20 and to support the wafer. The film forming apparatus 1 further includes the light irradiation mechanism 70 for irradiating laser light on the pin position portions of the wafer W placed on the upper surface of the substrate support 20 that are the specific portions corresponding to the positions where the support pins 30 protrude and retract so that the pin position portions can be heated. Therefore, the temperatures of the pin position portions of the wafer W, which are relatively low in the case of heating the wafer W only by the substrate support 20, can be corrected by the light irradiation mechanism 70. Accordingly, when the wafer W placed on the upper surface of the substrate support 20 where the support pins 30 protrude and retract is heated by the substrate support 20, the in-plane uniformity of the temperature of the wafer W can be improved. As a result, even a film of which thickness sensitively changes depending on a temperature, such as the a-Si film or the like, can be formed on the wafer W with a uniform thickness.

Further, in accordance with the present embodiment, it is not required to develop a new heating solution by the substrate support 20 in order to improve the in-plane uniformity of the temperature, development time can be saved. In addition, the light irradiation mechanism 70 can control the temperature correction amount based on the irradiation intensity or the irradiation time of the laser light, so that the light irradiation condition of the light irradiation mechanism 70 can be optimized within a short period of time.

Further, in the present embodiment, the light introducing paths 13a and 40b are formed above the substrate support 20 to overlap with the wafer W placed on the substrate support 20 in plan view. Therefore, an incident angle of the laser light irradiated to the wafer W through the light introducing paths 13a and 40b with respect to the wafer W is small, so that the efficiency of heating the pin position portions of the wafer W by the laser light increases. Especially, in the present embodiment, the light introducing paths 13a and 40b are formed directly above the trajectory in which the openings 20a move by the rotation of the substrate support 20. Accordingly, the incident angle of the laser light irradiated to the wafer W through the light introducing paths 13a and 40b with respect to the wafer W is approximately 0°, so that the efficiency of heating the pin position portions of the wafer W by the laser light increases.

When the heating efficiency of the laser light increases, a laser light source that emits laser light having a low output intensity can be used as the laser light source 71 of the light irradiation mechanism 70, so that the cost can be reduced.

In the above example, the irradiation intensity of the laser light from the laser light source 71 is fixed. However, a temperature sensor for measuring the temperatures of the pin position portions of the wafer W may be provided, and the irradiation intensity of the laser light may be adjusted based on the measurement result of the temperature sensor.

### Second Embodiment

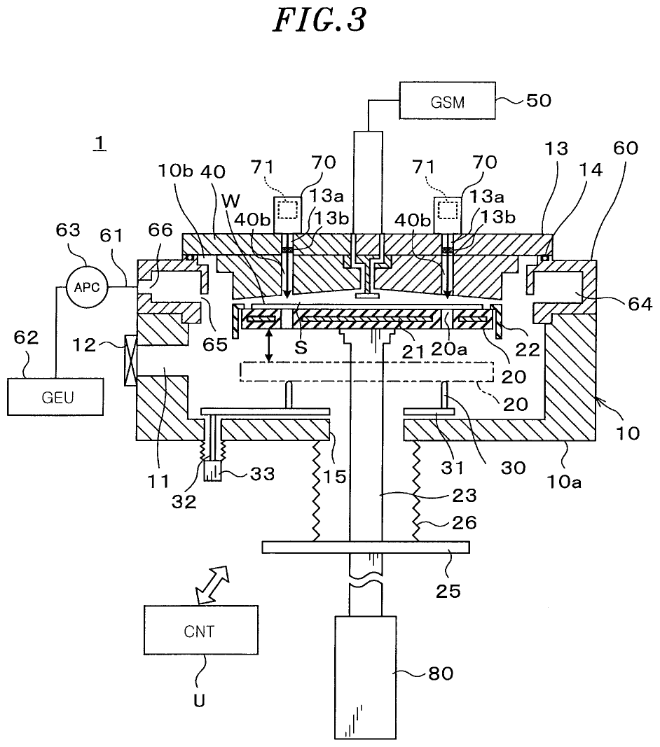

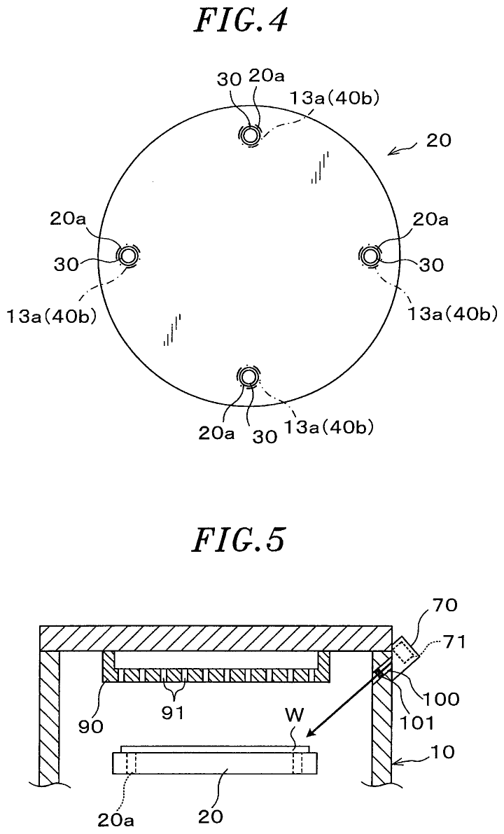

FIG. 3 is an explanatory diagram schematically showing a configuration of a film forming apparatus according to a second embodiment, and shows a cross section of a part of the film forming apparatus. FIG. 4 is a top view of the substrate support 20 and shows a positional relationship among openings 20a of a substrate support 20, support pins 30, and light introducing paths 13a and 40b in the present embodiment.

In the first embodiment, the driving mechanism 24 is configured to generate not only the driving force for vertically moving the support shaft member 23 but also the driving force for rotating the support shaft member 23. Further, the wafer W placed on the substrate support 20 connected to the supporting shaft member 23 is rotated by rotating the support shaft member 23 during the film formation.

On the other hand, in the present embodiment, the driving mechanism 80 connected to the support shaft member 23 shown in FIG. 3 is configured to generate only the driving force for vertically moving the support shaft member 23, and the wafer W is not rotated during the film formation.

Further, in the present embodiment, as shown in FIG. 4, the light introducing paths 13a and 40b are formed for each of the openings 20a of the substrate support 20. In other words, the light irradiation mechanism 70 is provided for each of the openings 20a of the substrate support 20.

Further, in the present embodiment, during the film formation, the light irradiation mechanism 70 irradiates laser light to the pin position portions of the wafer W not constantly but only for a predetermined period of time per unit time. For example, the laser light is continuously irradiated for the predetermined irradiation time every predetermined irradiation cycle at a fixed irradiation intensity. The irradiation cycle and the irradiation time are determined depending on the irradiation intensity of the laser light irradiated by the light irradiation mechanism 70 such that the temperatures of the pin position portions of the wafer W are within a desired range.

Further, in the present embodiment, the wafer W placed on the substrate support 20 is not rotated, so that the laser light can be irradiated from the light irradiation mechanism 70 for a longer period of time compared to that in the first embodiment. Therefore, a laser light source that emits light having a low output intensity can be used as the laser light source 71 of the light irradiation mechanism 70.

As described above, in the present embodiment as well, the light irradiation mechanism 70 can correct the temperatures of the pin position portions of the wafer W, which are relatively low in the case of heating the wafer W only by the substrate support 20. Therefore, in the present embodiment as well, the in-plane uniformity of the temperature of the wafer W can be improved, which makes it possible to form a film on the wafer W with a uniform thickness.

In the second embodiment, the light irradiation mechanism 70 does not constantly irradiate laser light during the film formation. However, the laser light may be constantly irradiated when the intensity of the laser light irradiated from the light irradiation mechanism 70 is low.

Further, in the present embodiment as well, it is assumed that the irradiation intensity of the laser light is fixed. Instead, a temperature sensor for measuring temperatures of the pin position portions of the wafer W may be provided, and the irradiation intensity of the laser light may be adjusted based on the measurement result of the temperature sensor.

(Another Example of a Formation Position of the Light Introducing Path)

FIG. 5 shows another example of a formation position of the light introducing path.

In the above-described example, the light introducing paths 13a and 40b are disposed above the substrate support 20 to overlap with the wafer W placed on the substrate support 20 in plan view. In other words, in the above-mentioned example, the light introducing paths 13a and 40b are disposed directly above the wafer W placed on the substrate support 20.

However, for example, when a shower plate 90 having a plurality of gas supply holes 91 is disposed to face the upper surface of the substrate support 20 in the processing chamber 10 as shown in FIG. 5, it is difficult to provide the light introducing path directly above the wafer W placed on the substrate support 20. Instead, in the example of FIG. 5, a light introducing path 100 is disposed at a position that does not overlap with the wafer W placed on the substrate support 20 in a plan view. Specifically, the light introducing path 100 is disposed on a wall (sidewall in the example of FIG. 5) of the processing chamber 10 located diagonally above the substrate support 20. The laser light emitted from the laser light source 71 of the light irradiation mechanism 70 outside the processing chamber 10 is introduced into the processing chamber 10 through the light introducing path 100. Further, the light introducing path 100 is provided with a window 101 similar to the window 13b.

Even when it is difficult to provide the light introducing path directly above the wafer W placed on the substrate support 20 due to the presence of the shower plate 90 or the like, the temperatures of the pin position portions of the wafer W can be corrected by the laser light from the light irradiation mechanism 70 by providing the light introducing path 100 at the position described in FIG. 5.

When the light introducing path is provided as shown in FIG. 5, i.e., when the laser light from the light irradiation mechanism 70 is obliquely irradiated to the wafer W, a part of the laser light irradiated to the wafer W may be reflected by the wafer W and directed to the shower plate 90. The laser light directed to the shower plate 90 may be reflected by the shower plate 90 and directed to the wafer W again. When the laser light reflected by the shower plate 90 is directed to the wafer W, an unnecessary portion of the wafer W may be heated. Therefore, the bottom surface of the shower plate 90 may be covered with a film that suppresses the reflection of laser light, or the shower plate 90 may be made of a material that absorbs laser light. Alternatively, the bottom surface of the shower plate 90 may be roughened.

In the example of FIG. 5, the light introducing path 100 is disposed obliquely above the substrate support 20. Alternatively, the light introducing path may be disposed obliquely below the substrate support 20. In this case, a reflection member that reflects the laser light introduced into the processing chamber 10 through the light introducing path toward the wafer W on the substrate support 20 is provided in the processing chamber 10.

In the above description, one light irradiation mechanism is set for one irradiation region. However, a plurality of light irradiation mechanisms may be set for one irradiation region.

Further, in the above description, the a-Si film is formed. However, the technique of the present disclosure can also be applied to the case of forming other types of films.

In the above description, the film forming apparatus has been described as an example. However, the technique of the present disclosure can also be applied to a substrate processing apparatus that includes a substrate support and performs processing other than film formation, e.g., an inspection apparatus for performing inspection or an etching apparatus.

The embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

The following configurations are also included in the technical scope of the present disclosure.

(1) There is provided a substrate processing apparatus for processing a substrate including: a substrate support having an upper surface on which a substrate is placed and serving to heat the substrate placed thereon; at least one substrate support pin configured to protrude from and retract below the upper surface of the substrate support and to support the substrate; and a light irradiation mechanism configured to irradiate light to a specific portion of the substrate placed on the upper surface of the substrate support, corresponding to a position where the at least one substrate support pin protrudes and retracts, to heat the specific portion.

In accordance with the configuration (1), in the case of heating the substrate by the substrate support, the substrate being placed on the upper surface of the substrate support where the substrate support pins protrudes and retracts, the in-plane uniformity of the temperature of the substrate can be improved.

(2) The substrate processing apparatus of the configuration (1) may further include a rotation driving mechanism configured to rotate the substrate support; and a controller configured to control the light irradiation mechanism and the rotation driving mechanism such that light is emitted from the light irradiation mechanism and irradiated to the specific portion of the substrate in accordance with the rotation of the substrate support.

(3) The substrate processing apparatus of the configuration (1) may further include a controller configured to control the light irradiation mechanism such that light from the light irradiation mechanism is irradiated to the specific portion only for a predetermined period of time per unit time.

(4) The substrate processing apparatus of any one of the configurations (1) to (3) may further include a processing chamber having therein the substrate support. The light irradiation mechanism may have a light source that emits light at an outside of the processing chamber. Further, the processing chamber may have a light introducing path that introduces light emitted from the light source from the outside of the processing chamber into the processing chamber, and the light introducing path is provided with a window.

(5) In the substrate processing apparatus of the configuration (4), the light introducing path may be disposed above the substrate support to overlap with the substrate placed on the substrate support in plan view.

(6) In the substrate processing apparatus of the configuration (4), the light introducing path may be disposed at a position that does not overlap with the substrate placed on the substrate support in plan view.

(7) In the substrate processing apparatus of any one of the configurations (1) to (6), the light may have directivity.

(8) In the substrate processing apparatus of the configuration (7), the light may be laser light.

(9) In the substrate processing apparatus of any one of the configurations (1) to (8), an opening through which an upper end of the at least one substrate support pin penetrates during vertical movement of the at least one substrate support pin may be formed in the upper surface of the substrate support, and a size of a light irradiation region with respect to the substrate placed on the substrate support may be 0.5 to 2.0 times greater than a size of the opening.

(10) There is provided a substrate processing method for processing a substrate including: a process of relatively moving a substrate support and at least one substrate support pin that protrudes from and retracts below an upper surface of the substrate support and placing the substrate on the upper surface of the substrate support; and a process of performing predetermined processing on the substrate placed on a heated upper surface of the substrate support. The process of performing the predetermined processing includes heating a specific portion of the substrate placed on the upper surface of the substrate support, corresponding to a position where the at least one substrate support pin protrudes and retracts by irradiating light from a light irradiation mechanism to the specific portion.

(11) In the substrate processing method of the configuration (10), in the process of performing the predetermined processing, the substrate support may be rotated, and in the process of heating, light may be emitted from the light irradiation mechanism and irradiated to the specific portion of the substrate placed on the upper surface of the substrate in accordance with the rotation of the substrate support.

(12) In the substrate processing method of the configuration (10), in the process of heating, the light from the light irradiation mechanism may be irradiated to the specific portion only for a predetermined period of time per unit time.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

What is claimed is:

1. A substrate processing apparatus for processing a substrate, comprising:
a substrate support having an upper surface on which a substrate is placed and serving to heat the substrate placed thereon;
at least one substrate support pin configured to protrude from and retract below the upper surface of the substrate support and to support the substrate; and
a light irradiation mechanism configured to irradiate light to a specific portion of the substrate placed on the upper surface of the substrate support, corresponding to a position where said at least one substrate support pin protrudes and retracts, to heat the specific portion.

2. The substrate processing apparatus of claim 1, further comprising:
a rotation driving mechanism configured to rotate the substrate support; and
a controller configured to control the light irradiation mechanism and the rotation driving mechanism such that light is emitted from the light irradiation mechanism and irradiated to the specific portion of the substrate in accordance with the rotation of the substrate support.

3. The substrate processing apparatus of claim 1, further comprising;
a controller configured to control the light irradiation mechanism such that light from the light irradiation mechanism is irradiated to the specific portion only for a predetermined period of time per unit time.

4. The substrate processing apparatus of claim 1, further comprising:
a processing chamber having therein the substrate support,
wherein the light irradiation mechanism has a light source that emits light at an outside of the processing chamber,
the processing chamber has a light introducing path that introduces light emitted from the light source from the outside of the processing chamber into the processing chamber, and
the light introducing path is provided with a window.

5. The substrate processing apparatus of claim 4, wherein the light introducing path is disposed above the substrate support to overlap with the substrate placed on the substrate support in plan view.

6. The substrate processing apparatus of claim 4, wherein the light introducing path is disposed at a position that does not overlap with the substrate placed on the substrate support in plan view.

7. The substrate processing apparatus of claim 1, wherein the light has directivity.

8. The substrate processing apparatus of claim 7, wherein the light is laser light.

9. The substrate processing apparatus of claim 1, wherein an opening through which an upper end of said at least one substrate support pin penetrates during vertical movement of said at least one substrate support pin is formed in the upper surface of the substrate support, and
a size of a light irradiation region with respect to the substrate placed on the substrate support is 0.5 to 2.0 times greater than a size of the opening.

10. A substrate processing method for processing a substrate, comprising:
relatively moving a substrate support and at least one substrate support pin that protrudes from and retracts below an upper surface of the substrate support and placing the substrate on the upper surface of the substrate support; and
performing predetermined processing on the substrate placed on a heated upper surface of the substrate support,
wherein said performing the predetermined processing includes heating a specific portion of the substrate placed on the upper surface of the substrate support, corresponding to a position where said at least one substrate support pin protrudes and retracts by irradiating light from a light irradiation mechanism to the specific portion.

11. The substrate processing method of claim 10, wherein in said performing the predetermined processing, the substrate support is rotated, and
in said heating, light is emitted from the light irradiation mechanism and irradiated to the specific portion of the substrate placed on the upper surface of the substrate in accordance with the rotation of the substrate support.

12. The substrate processing method of claim 10, wherein in said heating, the light from the light irradiation mechanism is irradiated to the specific portion only for a predetermined period of time per unit time.
